(19) United States
(12) Patent Application Publication
(10) Pub. No.: US 2020/0299858 A1
(43) Pub. Date: Sep. 24, 2020

(54) METHOD FOR PRODUCING GROUP III NITRIDE SEMICONDUCTOR

(71) Applicant: TOYODA GOSEI CO., LTD., Kiyosu-shi (JP)

(72) Inventors: Shiro YAMAZAKI, Kiyosu-shi (JP); Miki MORIYAMA, Kiyosu-shi (JP)

(21) Appl. No.: 16/817,128

(22) Filed: Mar. 12, 2020

(30) Foreign Application Priority Data
Mar. 18, 2019 (JP) 2019-049759

(51) Int. Cl. C30B 19/04; C30B 19/12; C30B 29/40; C30B 19/10; H01L 21/02

(52) U.S. Cl. CPC C30B 19/04; C30B 19/12; C30B 29/406; C30B 19/106; H01L 21/0242; H01L 21/0262; H01L 21/02389; H01L 21/02634; H01L 21/0254

(57) ABSTRACT

The present invention reduces warpage of a Group III nitride semiconductor crystal in a method for producing a Group III nitride semiconductor crystal on a seed substrate through a flux method. A Group III nitride semiconductor is grown so that the total Al amount at the interface is not more than 3×10¹⁴/cm², and the total Si amount at the interface is not more than 5×10¹⁴/cm². Here, the total amount at the interface refers to a total number of atoms per unit area of an interface between the grown Group III nitride semiconductor and the seed substrate. Thus, warpage can be reduced by growing a Group III nitride semiconductor through a flux method.

### BACKGROUND OF THE INVENTION

### Field of the Invention

The present invention relates to a method for producing a Group III nitride semiconductor through a flux method.

### Background Art

A flux method is a known technique for the crystal growth of a Group III nitride semiconductor, in which nitrogen is dissolved in a molten mixture of an alkali metal and a Group III element (e.g., Ga), to thereby achieve epitaxial growth of a Group III nitride semiconductor in the liquid phase. Generally, sodium (Na) is used as the alkali metal, and the technique is called a Na flux method.

In the flux method, an example of a seed substrate is a template substrate composed of a sapphire substrate on which a GaN layer had been formed through MOCVD or a GaN self-standing substrate.

Japanese Patent Application Laid-Open (kokai) No. 2015-157760 discloses that warpage of the grown Group III nitride semiconductor crystal can be reduced by reducing the Si concentration in the crystal to less than 2×10¹⁷/cm³.

However, in accordance with the studies of the present inventors, warpage of the grown GaN crystal was not sufficiently reduced in the conventional method.

### SUMMARY OF THE INVENTION

In view of the foregoing, an object of the present invention is to reduce warpage of a Group III nitride semiconductor crystal grown on a seed substrate through a flux method.

One aspect of the present invention is a method for producing a Group III nitride semiconductor including feeding a nitrogen-containing gas into a molten mixture of a Group III metal and a flux, to thereby grow a Group III nitride semiconductor on a seed substrate, wherein when the total number of atoms per unit area of an interface between the grown Group III nitride semiconductor and the seed substrate is defined as the total amount at the interface, the total Al amount at the interface is not more than 3×10¹⁴/cm², and the total Si amount at the interface is not more than 5×10¹⁴/cm².

In the present invention, crystal grains of the Group III nitride semiconductor in the vicinity of the interface with the seed substrate preferably have a diameter of not less than 14 μm and a density of not more than 1×10⁷/cm³. This allows further reducing warpage of Group III nitride semiconductor.

According to the present invention, warpage of the grown Group III nitride semiconductor crystal can be reduced.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a sketch showing the configuration of a crystal growth apparatus;

FIG. 2 is a graph showing the relationship between depth and Al density of GaN crystal according to Example 1;

FIG. 3 is a graph showing the relationship between depth and Si density of GaN crystal according to Example 1;

FIG. 4 is a graph showing the relationship between depth and Al density of GaN crystal according to Comparative Example 1; and

FIG. 5 is a graph showing the relationship between depth and Si density of GaN crystal according to Comparative Example 1.

### DETAILED DESCRIPTION OF PREFERRED EMBODIMENTS

The present invention is to grow a Group III nitride semiconductor crystal on a seed substrate through a flux method. First, the flux method will be described generally.

### (Outline of Flux Method)

The flux method employed in the present invention is a technique which includes feeding a nitrogen-containing gas to a molten mixture containing an alkali metal (flux) and a Group III metal (raw material), and dissolving the gas in the molten mixture, to thereby achieve epitaxial growth of a Group III nitride semiconductor in a liquid phase.

The Group III metal, serving as a raw material, is at least one metal selected from among gallium (Ga), aluminum (Al), and indium (In). Through modifying the proportions of the metal elements, the composition of the formed Group III nitride semiconductor can be controlled, and specifically, GaN, AlN, InN, AlGaN, InGaN, AlGaInN, and other semiconductors can be grown. Use of only Ga as a Group III metal is particularly preferred. In other words, the present invention is particularly suitable for the growth of GaN.

The alkali metal serving as a flux is generally sodium (Na), but potassium (K) or a mixture of Na and K may also be used. Furthermore, lithium (Li) or an alkaline earth metal may also be added.

To the molten mixture, carbon (C) may also be added. Addition of carbon results in acceleration of crystal growth. A dopant other than C may also be added to the molten mixture, for the purpose of controlling physical properties (e.g., the type conduction and magnetic properties) of the grown Group III nitride semiconductor, promoting crystal growth, suppressing generation of miscellaneous crystals, regulating the growth direction, or the like. For example, germanium (Ge) or the like may be used as an n-type dopant, and magnesium (Mg), zinc (Zn), calcium (Ca), or the like may be used as a p-type dopant.

The nitrogen-containing gas is a gas of nitrogen molecules, a gas of a compound including a nitrogen element (e.g., ammonia), or a mixture thereof. The nitrogen-containing gas may be mixed with an inert gas such as a rare gas.

### (Structure of Seed Substrate)

In the present invention, a seed substrate (seed crystal) is placed in the molten mixture, and a Group III nitride semiconductor is grown on the seed substrate. The seed substrate may be placed in the molten mixture before heating or pressurization or after achieving growth temperature and pressure through heating and pressurization. As the seed substrate, a self-standing substrate or a template substrate made of a Group III nitride semiconductor may be used.

The self-standing substrate may be formed of a Group III nitride semiconductor having arbitrary compositional proportions such as GaN, AlGaN, or AlN. Generally, a Group III nitride semiconductor having the same composition as that of the Group III nitride semiconductor to be grown through the flux method is used.

The template substrate is formed of an underlayer substrate, a buffer layer provided on the underlayer substrate, and a Group III nitride semiconductor layer which has a c-plane as a main plane and which is provided on the buffer layer.

The underlayer substrate may be formed of any material, so long that it allows a Group III nitride semiconductor to be grown on the substrate. Examples of the material which may be used in the invention include sapphire, ZnO, and spinel.

The Group III nitride semiconductor layer provided on the underlayer substrate may be formed of a Group III nitride semiconductor having arbitrary compositional proportions such as GaN, AlGaN, or AlN. Generally, a Group III nitride semiconductor having the same composition as that of the Group III nitride semiconductor to be grown through the flux method is used. The Group III nitride semiconductor layer may be formed through any technique such as MOCVD, HVPE, or MBE. However, from the viewpoints of crystallinity and growth time, MOCVD and HVPE are preferred.

The self-standing substrate may have any thickness. The Group III nitride semiconductor layer of the template substrate may have any thickness. However, the thickness is preferably not less than 2 μm in the both case. This is because the Group III nitride semiconductor layer may be melted back at an initial stage of crystal growth in the flux method. Therefore, the thickness of the self-standing substrate is required so that a through hole is not made on the self-standing substrate. Also in case of using the template substrate, the thickness of the Group III nitride semiconductor layer of the template substrate is required so that the underlayer substrate is not exposed by melting back. Here, melting back refers to dissolving the Group III nitride semiconductor in a molten mixture to remove it. However, in case of using the template substrate, when the Group III nitride semiconductor layer of the template substrate is too thick, a large warpage generally occurs on the seed substrate. Therefore, the thickness of the Group III nitride semiconductor layer of the template substrate is preferably not more than 10 μm.

A mask having a plurality of dotted windows may be formed on a top surface of the seed substrate. Seed crystal regions (i.e. the surface of the Group III nitride semiconductor as a start point for epitaxial growth of a Group III nitride semiconductor) are dotted by exposing the surface of the seed substrate from the windows.

Thus, a Group III nitride semiconductor is laterally grown at an initial stage of crystal growth by dotting the seed crystal regions in this way, and the dislocation density is reduced by bending dislocation or dislocation annihilation process, thereby improving the crystal quality. Since voids are formed in the crystal during growth, the grown Group III nitride semiconductor crystal can be easily separated from the seed substrate after the completion of crystal growth.

Seed crystal regions may be dotted by forming a groove on the surface of the seed substrate by etching.

A mask may be formed by any method such as ALD method (Atomic Layer Deposition method), CVD method (Chemical Vapor Deposition method), and sputtering. However, the ALD method is particularly preferred, thereby forming a mask having a dense and uniform thickness, and suppressing the mask from being melted during growth through the flux method. The mask is made of any flux-resistant material as long as a Group III nitride semiconductor does not grow from the mask. However, a material preferably does not contain Al due to the reason described later. For example, TiO₂, ZrO₂ or the like may be used. The thickness of the mask is preferably 10 nm to 500 nm.

The mask windows are preferably arranged in a periodic pattern. An equilateral triangular lattice pattern is particularly preferred. By arranging the windows in such a pattern, a Group III nitride semiconductor is uniformly grown from each seed crystal region, thereby improving the crystal quality of the Group III nitride semiconductor. When the underlayer substrate is a c-plane sapphire substrate, the orientation of each side preferably makes an angle of 5° to 15° with respect to sapphire a-plane.

The shape of each window may be any shape such as a circle, a triangle, a rectangle, and a hexagon. However, a circle or a regular hexagon is preferable to achieve more uniform crystal growth from the surface of the Group III nitride semiconductor exposed in each window. When the shape of the window is a regular hexagon, the orientation of each side is preferably an m-plane of the Group III nitride semiconductor.

### (Configuration of Crystal Growth Apparatus)

In the Group III nitride semiconductor production method according to the present invention, a crystal growth apparatus 1000 having, for example, the following configuration is employed. The crystal growth apparatus 1000 is employed for the growth of a Group III nitride semiconductor single crystal through an Na flux method.

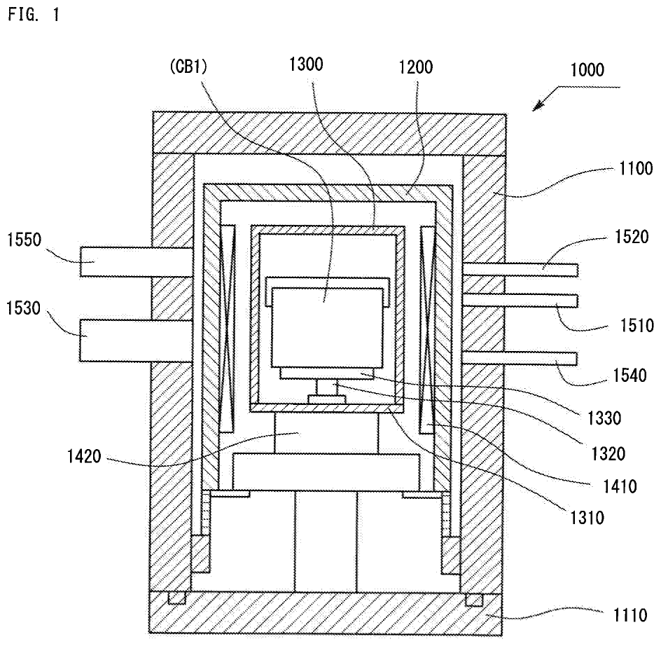

As shown in FIG. 1, the crystal growth apparatus 1000 has a pressure vessel 1100, a pressure vessel lid 1110, a middle chamber 1200, a reaction chamber 1300, a reaction chamber lid 1310, a rotation axis 1320, a turn table 1330, a side heater 1410, a lower heater 1420, a gas intake inlet 1510, a gas exhaust outlet 1520, a vacuum exhaust outlet 1530, a measurement ventilation hole 1540, and a Qmass mounting port 1550.

The pressure vessel 1100 serves as a housing of the crystal growth apparatus 1000. The pressure vessel lid 1110 is disposed under the pressure vessel 1100 in an orthogonal direction. The middle chamber 1200 is a chamber disposed inside the pressure vessel 1100. The reaction chamber 1300 is a chamber for accommodating a crucible CB1, in which a semiconductor single crystal is to be grown. The reaction chamber lid 1310 serves as a lid for the reaction chamber 1300.

The rotation axis 1320 is adapted to regular rotation and reverse rotation. The rotation axis 1320 receives rotary drive by a motor (not illustrated). The turn table 1330 allows rotation following the rotation axis 1320. The side heater 1410 and the lower heater 1420 are provided for heating the reaction chamber 1300.

The gas intake inlet 1510 is an inlet through which a nitrogen-containing gas is fed into the pressure vessel 1100. The gas exhaust outlet 1520 is an outlet through which a gas inside the pressure vessel 1100 is discharged. The vacuum exhaust outlet 1530 is an outlet for evacuating the pressure vessel 1100. The measurement ventilation hole 1540 is a hole through which a gas inside the pressure vessel 1100 is extracted for assay. On the gas flow downstream side of the ventilation hole 1540, an 02 sensor and a dew point meter are disposed. The Qmass mounting port 1550 is disposed for mounting a Qmass apparatus.

The crystal growth apparatus 1000 enables regulation of the temperature and pressure inside the crucible CB1 and rotating the crucible CB1. Thus, in the crucible CB1, a semiconductor single crystal can be grown from a seed crystal under conditions of interest.

### (Group III Nitride Semiconductor Production Method)

Next, the Group III nitride semiconductor production method according to the present invention will be described. Firstly, the furnace internal atmosphere is substituted by inert gas, and the furnace is heated. Thereafter, the furnace is evacuated so as to satisfactorily reduce oxygen in the furnace.

Then, the solid alkali metal and solid Group III metal are weighed in a glovebox in which the atmosphere (e.g., oxygen and dew point) is controlled. Subsequently, the seed substrate and the thus-weighed solid alkali metal and solid Group III metal in specific amounts are added to the crucible CB1.

Then, the crucible CB1 to which the raw materials have been added is placed on the turn table 1330 of the reaction chamber 1300, and the reaction chamber 1300 is closed. Further, the reaction chamber 1300 is confined in the pressure vessel 1100. Thereafter, the reaction chamber 1300 and the pressure vessel 1100 are evacuated, and a nitrogen-containing gas is fed into the reaction chamber 1300 and the pressure vessel 1100. When the pressure reached the crystal growth level, the inside temperature of the furnace is elevated to the crystal growth temperature. For example, the crystal growth temperature is 700° C. to 1,000° C., and the crystal growth pressure is 2 MPa to 10 MPa. In the course of temperature elevation, the alkali metal and the Group III metal in solid form are melted in the crucible CB1, to thereby form a liquid molten mixture.

When the temperature inside the reaction chamber 1300 has reached the crystal growth temperature, the crucible CB1 is rotated. Whereby the molten mixture is stirred, to thereby achieve a uniform mixing state of the molten mixture where the alkali metal concentration and the Group III metal concentration become uniform. When nitrogen is gradually dissolved in the molten mixture to a supersaturated state, growth of a Group III nitride semiconductor on the upper surface of the seed substrate begins.

While the crystal growth temperature and pressure are maintained, a Group III nitride semiconductor crystal is sufficiently grown on the upper surface of the seed substrate. Then, the rotation of the crucible CB1 and heating of the reaction chamber 1300 are terminated, whereby the temperature is lowered to room temperature, and the pressure is reduced to normal pressure. At this timing, growth of the Group III nitride semiconductor is terminated.

In the present invention, Group III nitride semiconductor crystal to be grown at an initial stage of crystal growth preferably contains as little Al or Si as possible. The grown Group III nitride semiconductor has a total Al amount at the interface of not more than 3×10¹⁴/cm² and a total Si amount at the interface of not more than 5×10¹⁴/cm². When a Group III nitride semiconductor is grown in this way, warpage of the grown Group III nitride semiconductor crystal can be reduced.

The term “total amount at the interface” refers to the total number of atoms per unit area of an interface between the grown Group III nitride semiconductor and the seed substrate. The total amount at the interface may be measured, for example, by measuring the density distribution of atoms in a thickness direction (direction perpendicular to the interface) with SIMS and integrating the density in a thickness direction.

Al or Si is unevenly distributed in a narrow range in the vicinity of the interface with the seed substrate in the grown Group III nitride semiconductor crystal, and Al or Si atoms of 0.5 atm % are concentrated in a thickness of 20 nm to 200 nm at the interface. Therefore, when the thickness of the grown Group III nitride semiconductor crystal is not less than 1,000 nm, the total Al or Si amount at the interface hardly depends on the thickness of the grown Group III nitride semiconductor crystal. Thus, in case of actual measurement of the total Al or Si amount at the interface, the Al or Si density does not need to be measured for all thicknesses, and the total amount at the interface can be satisfactorily evaluated by measuring the Al or Si density only in the vicinity of the interface.

The reason why warpage of the Group III nitride semiconductor crystal grown according to the present invention can be reduced is considered as follows. When Al or Si exists at the interface between the seed substrate and the molten mixture at the start of growth, Al or Si is easily nitrided before Ga is nitrided, thereby forming a nucleus as a starting point of the crystal growth. When a large amount of Al or Si exists, its nucleus is formed at high density.

A Group III nitride semiconductor crystal is grown around the nuclei. When a large amount of nuclei exist, crystal grains of Group III nitride semiconductor to be grown are small in size and high in density. On the contrary, when a small amount of nuclei exists, crystal grains of Group III nitride semiconductor to be grown are large in size and low in density.

The crystal grains generated at an initial stage of crystal growth are combined as growth proceeds, and crystal defects are reduced. Each of the crystal grains has a hexagonal pyramid shape. Here, when the crystal grains are combined each other, a structural difference occurs in a thickness direction, and stress is generated due to this. Stress causes the warpage of the Group III nitride semiconductor. The more the crystal grains are combined, the higher the stress is. Therefore, when a large amount of Al or Si exists at the interface between the seed substrate and the molten mixture at the start of growth, and crystal grains generated at an initial stage of crystal growth are smaller in size and higher in density, the warpage of the grown Group III nitride semiconductor crystal is larger. On the contrary, when a small amount of Al or Si exists at the interface between the seed substrate and the molten mixture at the start of growth, and crystal grains generated at an initial stage of crystal growth are larger in size and lower in density, the warpage of the grown Group III nitride semiconductor crystal is smaller.

As described above, the amount of Al or Si (i.e., the total Al or Si amount at the interface) existing at the interface between the seed substrate and the molten mixture at an initial stage of crystal growth affects the warpage of the grown Group III nitride semiconductor crystal. As long as the total Al amount at the interface is not more than 3×10¹⁴/cm², and the total Si amount at the interface is not more than 5×10¹⁴/cm², the warpage of the grown Group III nitride semiconductor crystal can be satisfactorily reduced. For example, the curvature radius may be not more than 5 m.

To further reduce the warpage of the grown Group III nitride semiconductor crystal, the total Al amount at the interface is preferably not more than 2×10¹⁴/cm², more preferably, not more than 1.5×10¹⁴/cm², and further preferably, 1×10¹⁴/cm². For the same reason, the total Si amount at the interface is preferably not more than 3×10¹⁴/cm², more preferably, not more than 2.5×10¹⁴/cm², and further preferably, not more than 2×10¹⁴/cm².

Crystal grains of the grown Group III nitride semiconductor crystal in the vicinity of the interface with the seed substrate preferably have a size (diameter) of not less than 14 μm and a density of not more than 1×10⁷/cm². More preferably, the size of crystal grains is 14 μm to 16 μm, and the density of crystal grains is 6×10⁵/cm² to 8×10⁵/cm². Here, the size of crystal grains is defined by the average diameter of the grains observed as follows. The observation cross-section was created by removing the surface of the as-formed surface in some micrometers to some ten micrometers through peeling, polishing or a similar technique, to thereby attain a flat surface. Then, the cross-section was observed under a fluorescent microscope or a cathode luminescent device. When the size and density of crystal grains are within this range, warpage of the grown Group III nitride semiconductor crystal can be reduced. More preferably, the size of crystal grains is 24 μm to 26 μm, and the density of crystal grains is 2×10⁵/cm² to 3×10⁵/cm². Further preferably, the size of crystal grains is 48 μm to 52 μm, and the density of crystal grains is 6×10⁴/cm² to 7×10⁴/cm².

### (Control of Total Amount at the Interface)

The total Al and Si amount at the interface can be reduced, for example, by the following methods. One method is to use a material having little impurity. Specifically, high purity materials are used as a solid alkali metal to be placed in the crucible CB1, a solid Group III metal, or a nitrogen gas to be fed to the furnace.

Another method is to shorten the working time from placement of a material in the crucible CB1 inside the glove box to transfer of the crucible CB1 to the furnace. This is because Al or Si remained in the glove box adheres to the material in the crucible CB1 or the crucible CB1 itself, and thus, the total Al or Si amount at the interface is increased.

Yet another method is to use a material not containing Al or Si as a material of the crucible CB1. For example, BN, PBN, yttria, Ta, and others may be used.

Yet another method is to sufficiently reduce impurities in the furnace. For example, impurities in the furnace can be reduced by substituting the atmosphere of the furnace with inert gas such as nitrogen gas, heating the inside of the furnace, and evacuating the furnace.

In case of a template substrate where sapphire is used as an underlayer substrate, yet another method is to form a protective film made of Ta on the back surface of the underlayer substrate.

Specific embodiments of the present invention will next be described. However, the present invention is not limited to these embodiments.

### Example 1

By use of the crystal growth apparatus 1000, a GaN crystal was grown on a seed substrate in the following manner. Firstly, the atmosphere of the furnace (reaction chamber 1300 and pressure vessel 1100) was substituted by nitrogen gas. The furnace was heated and evacuated, to thereby reduce the amounts of oxygen and water. Through this process, the oxygen concentration of the furnace internal atmosphere was adjusted to 0.02 ppm or lower at the start of growth of a GaN crystal.

Subsequently, a crucible CB1 made of alumina was placed in a glovebox under Ar, and a seed crystal, purity 6N (purity 99.9999%) Ga (solid), and 6N Na (solid) were placed in the crucible. A seed substrate formed of a sapphire substrate on which a flat and uniform GaN layer had been provided through MOCVD and a pattern of regular hexagons arranged in a honeycomb structure is formed by dry etching a part of the GaN layer was used. The atmosphere (oxygen and dew point) in the glove box was measured. The oxygen concentration was 0.03 ppm, and the dew point was −90° C. Sodium produced by Métaux Spéciaux—ER grade was used as a solid Na. After that, the crucible CB1 was left in the glove box. The time in the glove box was ten hours in total.

Then, the crucible CB1 was transferred to a furnace, and the furnace was tightly closed. Nitrogen was fed to the furnace so as to adjust the internal pressure to 2.87 MPa. Purity 6N nitrogen was used. While maintaining the pressure constant, the furnace was heated at 1° C./min to the growth temperature (856° C.), whereby growth of a GaN crystal on the seed substrate was started.

When the temperature reached the growth temperature, the nitrogen atmosphere of the lower chamber sealing the opening/closing port of the pressure vessel 1100 was substituted by dry air. Thus, air gradually entered from the outside of the furnace to the pressure vessel 1100, and further from the pressure vessel 1100 to the reaction chamber 1300. The oxygen concentration of the furnace internal atmosphere was 0.015 ppm at the start of growth, and gradually increased with the lapse of time. Ten hours after the start of growth, the oxygen concentration reached 0.02 ppm. Thereafter, the oxygen concentration was controlled to not more than 0.1 ppm by controlling the atmosphere outside the furnace.

Ninety hours after the start of growth of a GaN crystal, the temperature and pressure were changed to ambient temperature (25° C.) and atmospheric pressure, whereby the growth of a GaN crystal was terminated. The seed substrate was removed from the furnace and washed with ethanol or the like, to thereby remove Na and Ga. The grown GaN crystal was peeled from the seed substrate due to thermal stress during temperature dropping. The obtained GaN crystal has a thickness of 0.8 mm and a curvature radius of 9 m.

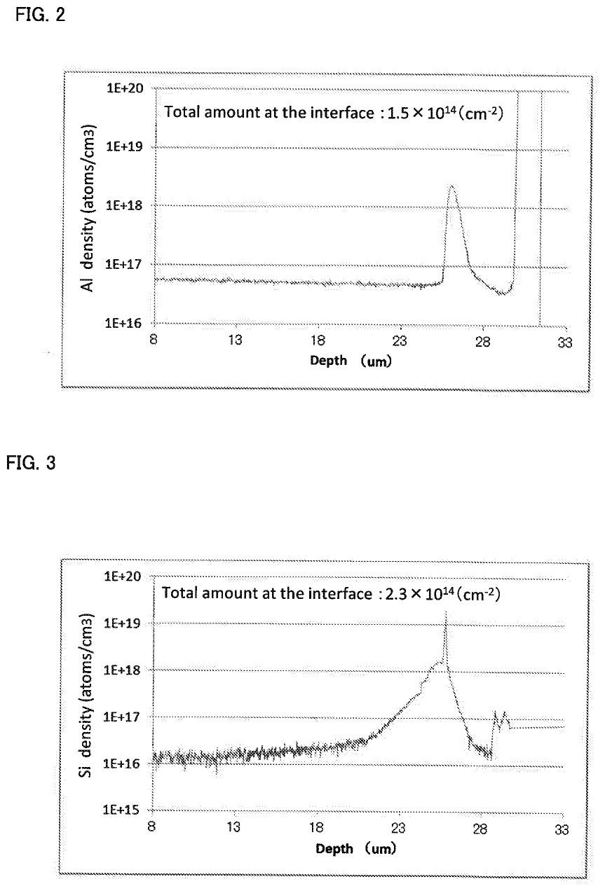

The Al density and Si density were obtained by SIMS analysis of the vicinity of the surface on the seed substrate side of the grown GaN crystal. FIG. 2 is a graph showing the relationship between depth and Al density (atoms/cm³) of the grown GaN crystal. FIG. 3 is a graph showing the relationship between depth and Si density (atoms/cm³) of the grown GaN crystal. Depth direction is a direction from the GaN crystal toward the seed substrate, and the area at a depth of 25.5 μm is an interface between the GaN crystal and the seed substrate. Impurity existing at the interface between the GaN crystal and the seed substrate is pushed into the seed substrate due to knock-on effect in SIMS analysis. The total amount at the interface was determined by integrating the density within a range where the density in the vicinity of the interface is not less than the lower limit of detection. As a result, the total Al amount at the interface was 1.5×10¹⁴/cm², and the total Si amount at the interface was 2.3×10¹⁴/cm².

### Comparative Example 1

A GaN crystal was grown on a seed substrate under the same conditions as in Example 1 except that the working time in the glove box was changed to twenty hours in total by prolonging the time for which the crucible CB1 is left in the glove box. The grown GaN crystal was peeled from the seed substrate in the same way as in Example 1. The thickness of the obtained GaN crystal was 0.7 mm and the curvature radius of the obtained GaN crystal was 0.5 m.

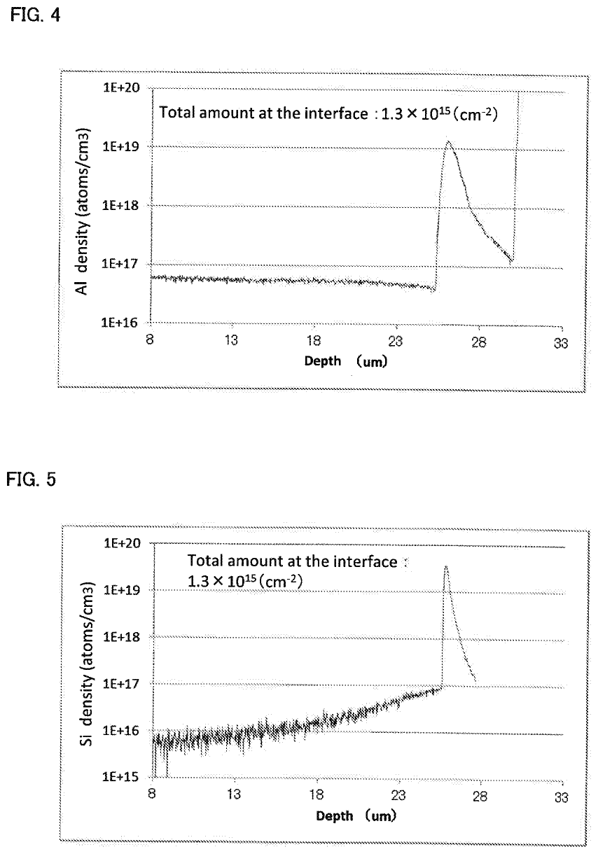

In the same way as in Example 1, the Al density and Si density were obtained by SIMS analysis of the vicinity of the surface on the seed substrate side of the grown GaN crystal. FIG. 4 is a graph showing the relationship between depth and Al density (atoms/cm³) of the grown GaN crystal. FIG. 5 is a graph showing the relationship between depth and Si density (atoms/cm³) of the grown GaN crystal. The total amount at the interface was determined in the same was as in Example 1. The total Al amount at the interface was 1.3×10¹⁵/cm², and the total Si amount at the interface was 1.3×10¹⁵/cm².

Only the working time in the glove box is different between Example 1 and Comparative Example 1. Therefore, Al or Si remained in the glove box adheres to the material in the crucible CB1 or the crucible CB1 itself by prolonging the time for which the crucible CB1 was left in the glove box. As a result, conceivably, the total Al or Si amount at the interface was larger in Comparative Example 1 than in Example 1. Thus, warpage of the grown GaN crystal was increased due to an increase in the total Al or Si amount at the interface.

### Example 2

A seed substrate formed of a sapphire substrate on which a GaN layer had been formed through MOCVD, an aluminum mask had been formed on the GaN layer, and a predetermined pattern had been exposed on the surface of the GaN layer was used. A predetermined pattern is a pattern of regular hexagonal columns arranged in a honeycomb structure. A GaN crystal was grown on a seed substrate under the same conditions as in Example 1 except the above. In the same way as in Example 1, warpage of the grown GaN crystal was reduced.

The Group III nitride semiconductor crystal obtained by the present invention can be used for a substrate for forming a semiconductor device.

What is claimed is:

1. A method for producing a Group III nitride semiconductor comprising feeding a nitrogen-containing gas into a molten mixture of a Group III metal and a flux, to thereby grow a Group III nitride semiconductor on a seed substrate, wherein when the total number of atoms per unit area of an interface between the grown Group III nitride semiconductor and the seed substrate is defined as the total amount at the interface, the total Al amount at the interface is not more than 3×10¹⁴/cm², and the total Si amount at the interface is not more than 5×10¹⁴/cm².

2. The Group III nitride semiconductor production method according to claim 1, wherein crystal grains of the Group III nitride semiconductor in the vicinity of the interface with the seed substrate have a diameter of not less than 14 μm and a density of not more than 1×10⁷/cm³.

3. The Group III nitride semiconductor production method according to claim 1, wherein the Group III nitride semiconductor grown on the seed substrate is GaN.

4. The Group III nitride semiconductor production method according to claim 2, wherein the Group III nitride semiconductor grown on the seed substrate is GaN.

5. The Group III nitride semiconductor production method according to claim 3, wherein a crucible in which Ga, Na, and the seed substrate are placed is made of at least one selected from a group consisting of alumina, BN, PBN, yttria, and Ta.

6. The Group III nitride semiconductor production method according to claim 4, wherein a crucible in which Ga, Na, and the seed substrate are placed is made of at least one selected from a group consisting of alumina, BN, PBN, yttria, and Ta.

7. The Group III nitride semiconductor production method according to claim 3, wherein the seed substrate is a template substrate comprising a GaN layer as a seed on a sapphire substrate and a back surface of the sapphire substrate is coated with a protective film.

8. The Group III nitride semiconductor production method according to claim 4, wherein the seed substrate is a template substrate comprising a GaN layer as a seed on a sapphire substrate and a back surface of the sapphire substrate is coated with a protective film.
